(19) United States
(12) Patent Application Publication
(10) Pub. No.: US 2024/0308018 A1
(43) Pub. Date: Sep. 19, 2024

(54) SUBSTRATE PROCESSING APPARATUS AND INFORMATION PROCESSING SYSTEM

(71) Applicant: EBARA CORPORATION, Tokyo (JP)

(72) Inventors: Yuta SUZUKI, Tokyo (JP); Hiroki TAKAHASHI, Tokyo (JP); Akira NAKAMURA, Tokyo (JP); Katsuhide WATANABE, Tokyo (JP); Hisanori MATSUO, Tokyo (JP); Takahito KAGOSHIMA, Tokyo (JP)

(21) Appl. No.: 18/570,406

(22) PCT Filed: May 24, 2022
(86) PCT No.: PCT/JP2022/021203

§ 371 Date: Dec. 14, 2023

(30) Foreign Application Priority Data
Jun. 15, 2021 (JP) 2021-099286

(51) Int. Cl. B24B 37/005; H01L 21/67

(52) U.S. Cl. CPC B24B 37/005; H01L 21/67253; H01L 21/67288

(57) ABSTRACT

Included are: at least one sensor that detects a physical quantity of an object during polishing and/or during cleaning and/or during drying of a substrate; a conversion section that converts a sensor value during polishing and/or during cleaning and/or during drying detected by the sensor into a feature amount for each processing step with respect to a trained machine learning model; and an inference section that outputs at least one predicted value of a number of defects, a size of a defect, and a position of a defect in a target substrate by inputting target data including the feature amount to the trained machine learning model.

### TECHNICAL FIELD

The present invention relates to a substrate processing apparatus and an information processing system.

### BACKGROUND ART

The cleaning performance of a substrate processing apparatus (for example, a polishing apparatus) is evaluated, for example, by measuring a substrate (specifically, a wafer) discharged from the apparatus after finishing polishing, cleaning, and drying processing with a dedicated defect inspection apparatus (See, for example, Patent Literature 1.). Since defect inspection requires cost (mainly time), it is difficult to perform total inspection after substrate processing (for example, polishing, cleaning, drying) at a manufacturing site, and sampling inspection is performed.

### CITATION LIST

### Patent Literature

Patent Literature 1: JP 2002-257533 A

### SUMMARY OF INVENTION

### Technical Problem

However, there is also a possibility that a defective product is generated due to insufficient cleaning of a substrate (specifically, a wafer) that has not been inspected.

The present invention has been made in view of the above problem, and an object of the present invention is to provide a substrate processing apparatus and an information processing system capable of estimating whether or not a substrate after substrate processing is defective without being inspected by a defect inspection apparatus.

### Solution to Problem

A substrate processing apparatus according to an aspect of the present invention includes: at least one sensor that detects a physical quantity of an object during polishing and/or during cleaning and/or during drying of a substrate; a conversion section that converts a sensor value during polishing and/or during cleaning and/or during drying detected by the sensor into a feature amount for each processing step with respect to a trained machine learning model; and an inference section that outputs at least one predicted value of a number of defects, a size of a defect, and a position of a defect in a target substrate by inputting target data including the feature amount to the trained machine learning model, in which the trained machine learning model is trained using a learning data set whose input data includes a feature amount obtained by converting a sensor value during polishing and/or during cleaning detected by the sensor in a target production line or a production line of an identical type with the target production line for each processing step, and whose output data is at least one of a number of defects, a size of a defect, and a position of a defect in the substrate.

According to this configuration, since at least one predicted value of the number of defects, the size of the defect, and the position of the defect of the substrate after substrate processing is obtained without being inspected by a defect inspection apparatus, it is possible to estimate whether or not the substrate after the substrate processing is a defective product without being inspected by the defect inspection apparatus.

Furthermore, in the substrate processing apparatus, the input data at the time of training of the machine learning model may further include a stay time of staying in a unit counted for each unit included in the substrate processing apparatus, the substrate processing apparatus may further include a unit stay time counting section that counts a stay time in the unit for each unit included in the substrate processing apparatus, and the target data input to the trained machine learning model may further include the stay time in the unit counted for each unit by the unit stay time counting section.

Furthermore, in the substrate processing apparatus, the input data at the time of training of the machine learning model may further include a second feature amount obtained by converting a position of a member used for polishing or cleaning, the conversion section may convert the position of the member used for polishing or cleaning into the second feature amount, and the target data input to the trained machine learning model may further include the second feature amount for each member converted by the conversion section.

Furthermore, in the substrate processing apparatus, the input data at the time of training of the machine learning model may further include recipe information including a command value for a unit included in the substrate processing apparatus, and the target data input to the trained machine learning model may further include recipe information including a command value for a unit included in the substrate processing apparatus.

Furthermore, the substrate processing apparatus may further include: a regression analysis section that outputs a correlation parameter representing a correlation with one of a number of defects, a size of a defect, and a position of a defect in the substrate for each of a plurality of sensor values according to a predetermined regression analysis algorithm; a reception section that receives at least one sensor that outputs a sensor value that is a basis of the feature amount included in the input data of the machine learning model; and a learning section that trains the machine learning model again with the feature amount obtained by converting the sensor value of the received sensor, in which the inference section may output the predicted value using the machine learning model trained again by the learning section.

An information processing system according to another aspect of the present invention includes: a conversion section that converts a sensor value during polishing and/or during cleaning and/or during drying of a substrate detected by a sensor included in a substrate processing apparatus into a feature amount for each processing step with respect to a trained machine learning model; and an inference section that outputs at least one predicted value of a number of defects in the substrate, a size of a defect, and a position of a defect in the substrate by inputting target data including the feature amount, in which the trained machine learning model is trained using a learning data set whose input data includes a feature amount obtained by converting a sensor value during polishing and/or during cleaning detected by the sensor in a target production line or a production line of an identical type with the target production line for each processing step, and whose output data is at least one of a number of defects, a size of a defect, and a position of a defect in the substrate.

### Advantageous Effects of Invention

According to one aspect of the present invention, since at least one predicted value of the number of defects, the size of the defect, and the position of the defect of the substrate after the substrate processing is obtained without being inspected by the defect inspection apparatus, it is possible to estimate whether or not the substrate after the substrate processing is a defective product without being inspected by the defect inspection apparatus.

### BRIEF DESCRIPTION OF DRAWINGS

FIG. 1 is a diagram illustrating an example of a schematic configuration of a substrate processing apparatus according to the present embodiment.

FIG. 2 is an example of a block diagram illustrating an example of a schematic configuration of a control section according to the present embodiment.

FIG. 3 is a graph illustrating an example of a stay time in each unit according to the present embodiment.

FIG. 4 is an example of a data structure of a feature amount included in input data input to a machine learning model.

FIG. 5 is an example of a data structure of a stay time for each unit included in input data input to a machine learning model.

FIG. 6A is a schematic diagram for explaining an example of a learning process of a machine learning model.

FIG. 6B is a schematic diagram for explaining an example of an inference process of the machine learning model.

FIG. 7 is an example of a graph for comparing an actual measured value of the number of defects with a predicted value of the number of defects.

FIG. 8A is a schematic diagram for explaining a first modification of the learning process of the machine learning model.

FIG. 8B is a schematic diagram for explaining a first modification of the inference process of the machine learning model.

FIG. 9A is a schematic diagram for explaining a second modification of the learning process of the machine learning model.

FIG. 9B is a schematic diagram for explaining a second modification of the inference process of the machine learning model.

FIG. 10A is a schematic diagram for explaining a third modification of the learning process of the machine learning model.

FIG. 10B is a schematic diagram for explaining a third modification of the inference process of the machine learning model.

FIG. 11A is a schematic configuration diagram according to a first modification of the present embodiment.

FIG. 11B is a schematic configuration diagram according to a second modification of the present embodiment.

FIG. 12A is a schematic configuration diagram according to a third modification of the present embodiment.

FIG. 12B is a schematic configuration diagram according to a fourth modification of the present embodiment.

### DESCRIPTION OF EMBODIMENTS

Hereinafter, each embodiment will be described with reference to the drawings. However, unnecessarily detailed description may be omitted. For example, a detailed description of a well-known matter and a duplicate description of substantially the same configuration may be omitted. This is to avoid unnecessary redundancy of the following description and to facilitate understanding of those skilled in the art. In the present embodiment, as an example of a substrate processing apparatus, a polishing apparatus that performs chemical mechanical polishing (CMP) to flatten a surface of a substrate W will be described.

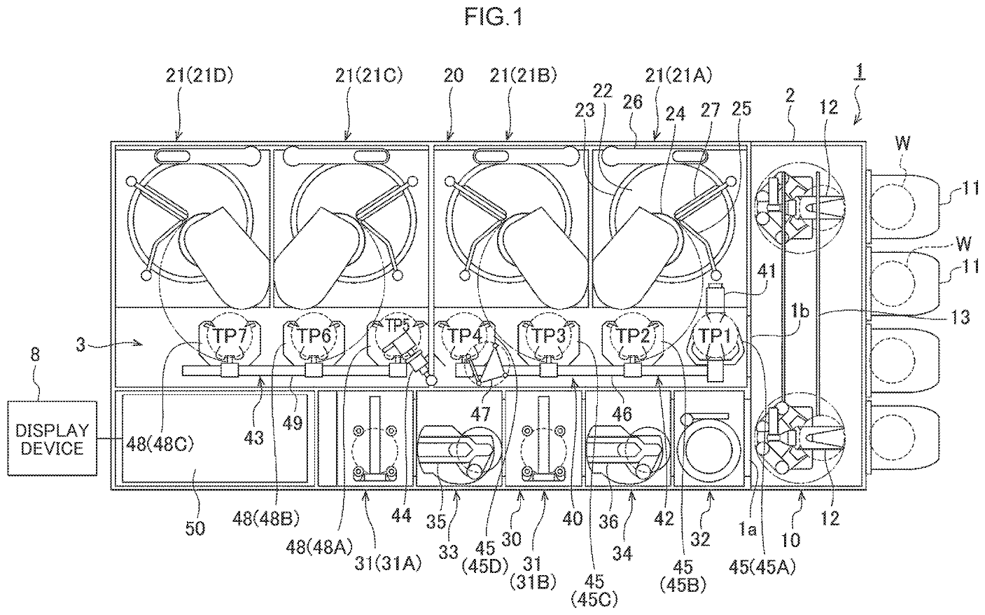

FIG. 1 is a diagram illustrating an example of a schematic configuration of a substrate processing apparatus according to the present embodiment. As illustrated in FIG. 1, a substrate processing apparatus 1 is a polishing apparatus that performs chemical mechanical polishing (CMP) to flatten the surface of the substrate W such as a silicon wafer (Hereinafter, it is also simply referred to as a wafer.).

As illustrated in FIG. 1, the substrate processing apparatus 1 includes, for example, a rectangular box-shaped housing 2. The housing 2 is formed in a substantially rectangular shape in plan view. The housing 2 includes a substrate transport path 3 extending in a longitudinal direction at a center thereof. A load/unload unit 10 is disposed at one end portion of the substrate transport path 3 in the longitudinal direction. A polishing unit 20 is disposed on one side in a width direction of the substrate transport path 3, that is, in a direction orthogonal to the longitudinal direction in plan view, and a cleaning unit 30 is disposed on the other side. The substrate transport path 3 is provided with a substrate transport unit 40 that transports the substrate W. Furthermore, the substrate processing apparatus 1 includes a control section 50 that integrally controls operations of the load/unload unit 10, the polishing unit 20, the cleaning unit 30, and the substrate transport unit 40.

The load/unload unit 10 includes a front load unit 11 that accommodates the substrate W. A plurality of the front load units 11 is provided on a side surface on one side in the longitudinal direction of the housing 2. The plurality of front load units 11 is arranged in the width direction of the housing 2. For example, an open cassette, a standard manufacturing interface (SMIF) pod, or a front opening unified pod (FOUP) is mounted on each of the front load units 11. Each of the SMIF and the FOUP is a sealed container in which a cassette of the substrate W is stored and covered with a partition wall, and can maintain an environment independent of an external space.

Furthermore, the load/unload unit 10 includes two transport robots 12 that take in and out the substrate W from the front load units 11, and a traveling mechanism 13 that causes each of the transport robots 12 to travel along the arrangement of the front load units 11. Each of the transport robots 12 includes two hands on upper and lower sides, and uses these two bands separately before processing the substrate W and after processing the substrate W. For example, each transport robot 12 uses the upper hand in the case of returning the substrate W to the front load units 11, and uses the lower hand in the case of taking out the substrate W before being processed from the front load units 11.

The polishing unit 20 includes a plurality of polishing devices 21 (21A, 21B, 21C, and 21D) that polish the substrate W. The plurality of polishing devices 21 is arranged in the longitudinal direction of the substrate transport path 3. Each of the polishing devices 21 includes a polishing table 23 that rotates a polishing pad 22 having a polishing surface, a top ring 24 that holds the substrate W and polishes the substrate W while pressing the substrate W against the polishing pad 22 on the polishing table 23, a polishing liquid supply nozzle 25 that supplies a polishing liquid, a dressing liquid, or the like to the polishing pad 22, a dresser 26 that performs dressing of the polishing surface of the polishing pad 22, and an atomizer 27 that atomizes a mixed fluid of a liquid such as pure water and a gas such as nitrogen gas or a liquid such as pure water and injects the atomized mixed fluid or liquid onto the polishing surface.

The polishing device 21 presses the substrate W against the polishing pad 22 by the top ring 24 while supplying the polishing liquid from the polishing liquid supply nozzle 25 onto the polishing pad 22, and moves the top ring 24 and the polishing table 23 relative to each other, thereby polishing the substrate W to flatten the surface of the substrate W. Furthermore, the top ring 24 includes a plurality of pressurization and depressurization areas (for example, airbags) arranged concentrically. The top ring 24 adjusts the degree of pressing of the substrate W against the polishing pad 22 by adjusting the pressure in the plurality of pressurization and depressurization areas.

In the dresser 26, hard particles such as diamond particles and ceramic particles are fixed to a rotating portion at a tip in contact with the polishing pad 22, and the rotating portion is swung while being rotated, so that the entire polishing surface of the polishing pad 22 is uniformly dressed to form a flat polishing surface.

The atomizer 27 washes away polishing waste, abrasive grains, and the like remaining on the polishing surface of the polishing pad 22 with a high-pressure fluid to clean the polishing surface and perform dressing work of the polishing surface by the dresser 26, that is, reproduction of the polishing surface.

The cleaning unit 30 includes a plurality of cleaning devices 31 (31A and 31B) for cleaning the substrate W and a substrate drying device 32 for drying the cleaned substrate W. The plurality of cleaning devices 31 and the substrate drying device 32 are arranged in the longitudinal direction of the substrate transport path 3. A first transport chamber 33 is provided between the cleaning device 31A and the cleaning device 31B. The first transport chamber 33 is provided with a transport robot 35 that transports the substrate W between the substrate transport unit 40, the cleaning device 31A, and the cleaning device 31B.

The transport robot 35 includes two hands on upper and lower sides, and uses these two bands separately before cleaning the substrate W in the cleaning device 31A and after cleaning the substrate W in the cleaning device 31A. For example, the transport robot 35 uses the lower hand in the case of taking out the substrate W before cleaning from a temporary placing stand (also referred to as a wafer station) 47 to be described later and transporting the substrate W to the cleaning device 31A, and uses the upper hand in the case of taking out the substrate W from the cleaning device 31A after cleaning and transporting the substrate W to the cleaning device 31.

Furthermore, a second transport chamber 34 is provided between the cleaning device 31B and the substrate drying device 32. The second transport chamber 34 is provided with a transport robot 36 that transports the substrate W between the cleaning device 31B and the substrate drying device 32.

The cleaning device 31 includes a roll sponge (hereinafter, also referred to as a roll) type cleaning module, and cleans the substrate W using the cleaning module. Note that the cleaning device 31A and the cleaning device 31B may be the same type or different types of cleaning modules. Furthermore, the cleaning device 31A and the cleaning device 31B may include, for example, a pencil sponge (Hereinafter, also referred to as a pen.) type cleaning module or a two-fluid jet type cleaning module instead of the roll sponge type cleaning module. Here, in the case of the two-fluid jet type cleaning module, the two-fluid is, for example, a mixture of nitrogen (N2) and pure water.

The substrate drying device 32 includes, for example, a drying module that performs nitrogen gas (N2) drying or rotagoni drying using iso-propyl alcohol (IPA). After the substrate W is subjected to rotagoni drying, a shutter 1a provided on a partition wall between the substrate drying device 32 and the load/unload unit 10 is opened, and the substrate W is carried out from the substrate drying device 32 by the transport robot 12.

The substrate transport unit 40 includes a lifter 41, a first linear transporter 42, a second linear transporter 43, and a swing transporter 44. In the substrate transport path 3, a first transport position TP1, a second transport position TP2, a third transport position TP3, a fourth transport position TP4, a fifth transport position TP5, a sixth transport position TP6, and a seventh transport position TP7 are set in order from a side of the load/unload unit 10.

The lifter 41 is a mechanism that transports the substrate W up and down at the first transport position TP1. The lifter 41 receives the substrate W from the transport robot 12 of the load/unload unit 10 at the first transport position TP1. Then, the lifter 41 delivers the substrate W received from the transport robot 12 to the first linear transporter 42. A shutter 1b is provided on a partition wall between the first transport position TP1 and the load/unload unit 10, and when the substrate W is transported, the shutter 1b is opened and the substrate W is delivered from the transport robot 12 to the lifter 41.

The first linear transporter 42 is a mechanism that transports the substrate W between two of the first transport position TP1, the second transport position TP2, the third transport position TP3, and the fourth transport position TP4. The first linear transporter 42 includes a plurality of transport hands 45 (45A, 45B, 45C, and 45D) and a linear guide mechanism 46 that moves each of the transport hands 45 in a horizontal direction at a plurality of heights.

The transport hand 45A moves between the first transport position TP1 and the fourth transport position TP4 by the linear guide mechanism 46. The transport hand 45A is a pass hand for receiving the substrate W from the lifter 41 and delivering the substrate W to the second linear transporter 43.

The transport hand 45B moves between the first transport position TP1 and the second transport position TP2 by the linear guide mechanism 46. The transport hand 45B receives the substrate W from the lifter 41 at the first transport position TP1 and delivers the substrate W to the polishing device 21A at the second transport position TP2. The transport hand 45B is provided with a lifting drive unit, and moves up when the substrate W is delivered to the top ring 24 of the polishing device 21A, and moves down after the substrate W is delivered to the top ring 24. Note that the transport hand 45C and the transport hand 45D are also provided with a similar lifting drive unit.

The transport hand 45C moves between the first transport position TP1 and the third transport position TP3 by the linear guide mechanism 46. The transport hand 45C receives the substrate W from the lifter 41 at the first transport position TP1 and delivers the substrate W to the polishing device 21B at the third transport position TP3. Furthermore, the transport hand 45C also functions as an access hand that receives the substrate W from the top ring 24 of the polishing device 21A at the second transport position TP2 and delivers the substrate W to the polishing device 21B at the third transport position TP3.

The transport hand 45D moves between the second transport position TP2 and the fourth transport position TP4 by the linear guide mechanism 46. The transport hand 45D functions as an access hand that receives the substrate W from the top ring 24 of the polishing device 21A or the polishing device 21B at the second transport position TP2 or the third transport position TP3 and delivers the substrate W to the swing transporter 44 at the fourth transport position TP4.

The swing transporter 44 includes a hand movable between the fourth transport position TP4 and the fifth transport position TP5, and delivers the substrate W from the first linear transporter 42 to the second linear transporter 43. Furthermore, the swing transporter 44 delivers the substrate W polished by the polishing unit 20 to the cleaning unit 30. The temporary placing stand 47 for the substrate W is provided on a side of the swing transporter 44. The swing transporter 44 vertically inverts the substrate W received at the fourth transport position TP4 or the fifth transport position TP5 and places the substrate W on the temporary placing stand 47. The substrate W placed on the temporary placing stand 47 is transported to the first transport chamber 33 by the transport robot 35 of the cleaning unit 30.

The second linear transporter 43 is a mechanism that transports the substrate W between two of the fifth transport position TP5, the sixth transport position TP6, and the seventh transport position TP7. The second linear transporter 43 includes a plurality of transport hands 48 (48A, 48B, and 48C) and a linear guide mechanism 49 that moves each of the transport hands 45 in the horizontal direction at a plurality of heights. The transport hand 48A moves between the fifth transport position TP5 and the sixth transport position TP6 by the linear guide mechanism 49. The transport hand 45A functions as an access hand that receives the substrate W from the swing transporter 44 and delivers the substrate W to the polishing device 21C.

The transport hand 48B moves between the sixth transport position TP6 and the seventh transport position TP7. The transport hand 48B receives the substrate W from the polishing device 21C and functions as an access hand that delivers the substrate W to the polishing device 21D. The transport hand 48C moves between the seventh transport position TP7 and the fifth transport position TP5. The transport hand 48C functions as an access hand that receives the substrate W from the top ring 24 of the polishing device 21C or the polishing device 21D at the sixth transport position TP6 or the seventh transport position TP7 and delivers the substrate W to the swing transporter 44 at the fifth transport position TP5. Note that, although the description is omitted, the operations of the transport hands 48 at the time of transporting the substrate W are similar to the operation of the first linear transporter 42 described above.

The substrate processing apparatus 1 includes at least one sensor (not illustrated) that detects a physical quantity of an object during polishing and/or during cleaning and/or during drying of a substrate (for example, a wafer). The physical quantity of the object is, for example, as follows during polishing.
Rotation speed and/or torque of the polishing table 23
Rotation speed and/or torque of the top ring 24
Air bag pressure of the top ring 24
Rotation speed and/or load of the dresser 26
Slurry/water flow rate
Flow rate of the atomizer 27
Flow rate of nitrogen (N2) in the atomizer 27

The physical quantity of the target is, for example, as follows during cleaning.
Roll rotation speed and/or torque and/or load
Pen rotation speed and/or torque and/or load
Chemical liquid/water flow rate
Wafer rotation speed
Flow rate of nitrogen (N2)

The physical quantity of the object is, for example, as follows during drying.
Flow rate of nitrogen (N2)
Flow rate of iso-propyl alcohol (IPA)

As an example of the sensor, the substrate processing apparatus 1 may include a sensor that detects a table rotation speed and/or torque, a sensor that detects a top ring rotation speed and/or torque, a sensor that detects a top ring airbag pressure, a sensor that detects a dresser rotation speed and/or a load, a sensor that detects a flow rate of slurry/water, and a sensor that detects a flow rate of slurry/water.

Furthermore, the substrate processing apparatus 1 may include a sensor that detects a roll rotation speed and/or torque and/or load of the cleaning device 31, a sensor that detects a pen rotation speed and/or torque and/or load of the cleaning device 31, a sensor that detects a flow rate of the chemical liquid/water of the cleaning device 31, and a sensor that detects a wafer rotation speed of the cleaning device 31.

Furthermore, the substrate processing apparatus 1 may include a sensor that detects a flow rate of nitrogen (N2) and a sensor that detects a flow rate of iso-propyl alcohol (IPA).

Hereinafter, each of the members constituting the load/unload unit 10, the polishing unit 20, the cleaning unit 30, and the substrate transport unit 40 is referred to as a unit.

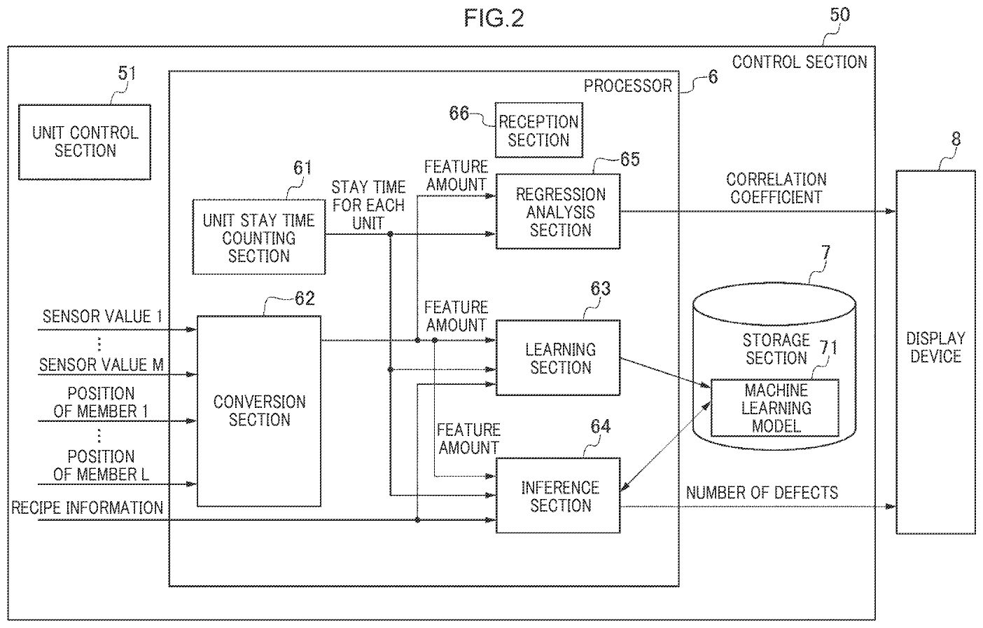

FIG. 2 is a block diagram illustrating an example of a schematic configuration of a control section according to the present embodiment. As illustrated in FIG. 2, a control section 50 includes a unit control section 51, a processor 6, and a storage section 7.

The unit control section 51 integrally controls operation of each unit of the load/unload unit 10, the polishing unit 20, the cleaning unit 30, and the substrate transport unit 40.

A trained machine learning model 71 is stored in the storage section 7. The trained machine learning model 71 is trained using a learning data set whose input data includes a feature amount obtained by converting a sensor value during polishing and/or during cleaning detected by a sensor in a target production line or a production line of the same type as the target production line for each processing step and whose output data is at least one of the number of defects, a size of a defect, and a position of a defect in the substrate. In the present embodiment, as an example, the output data of the learning data set will be described as the number of defects in the substrate. Here, the feature amount is an average, a maximum, a minimum, a total, a median, a standard deviation, a variance, kurtosis, or skewness of time-series values of the sensor, or an average, a maximum, a minimum, a total, a median, a standard deviation, a variance, kurtosis, or skewness of time-series data of differential values of the sensor.

The processor 6 functions as a unit stay time counting section 61, a conversion section 62, a learning section 63, an inference section 64, a regression analysis section 65, and a reception section 66 by reading and executing a predetermined program from the storage section 7.

The conversion section 62 converts a sensor value during polishing and/or during cleaning and/or during drying detected by the sensor into a feature amount for each processing step with respect to the trained machine learning model.

The learning section 63 trains the machine learning model 71 using a learning data set whose input data includes a feature amount obtained by converting a sensor value during polishing and/or during cleaning detected by a sensor in a target production line or a production line of the same type as the target production line for each processing step and whose output data is at least one of the number of defects in the substrate, the size of the defect, and the position of the defect in the substrate.

The inference section 64 outputs at least one predicted value of the number of defects, the size of the defect, and the position of the defect in the target substrate by inputting target data including the feature amount to the trained machine learning model.

The regression analysis section 65 outputs a correlation parameter (for example, a correlation coefficient) representing a correlation with any one of the number of defects, the size of the defect, and the position of the defect in the substrate for each of a plurality of the sensor values according to a predetermined regression analysis algorithm. Here, the regression analysis algorithm may be least absolute shrinkage and selection operator (LASSO) regression, Ridge regression, support vector regression (SVR), random forest regression (RFR), or Light GBM. The regression analysis section 65 may display this correlation parameter (for example, the correlation coefficient) on a display device 8. As a result, a worker or a user of the substrate processing apparatus 1 can confirm the correlation parameter (for example, the correlation coefficient).

The reception section 66 receives, for example, at least one sensor that outputs a sensor value to be a basis of a feature amount included in input data of a machine learning model from the worker or the user who has confirmed the output correlation parameter (for example, correlation coefficient). At this time, for example, the worker or the user inputs or selects a sensor that outputs a sensor value that is a basis of a feature amount having a high correlation. Then, the learning section 63 trains the previous machine learning model 71 again with the feature amount obtained by converting the received sensor value of the sensor. The inference section 64 outputs the predicted value using the machine learning model trained again by the learning section 63. According to this configuration, the worker or the user can improve the prediction accuracy after retaining of the machine learning model 71 by receiving, for example, a sensor that outputs a sensor value that is a basis of a feature amount having a high correlation with the reception section 66.

In the present embodiment, as an example, the input data at the time of training of the machine learning model further includes a stay time in the unit counted for each unit included in the substrate processing apparatus. On the premise of this, the unit stay time counting section 61 counts the stay time in the unit for each unit included in the substrate processing apparatus 1. In the present embodiment, as an example, the target data input to the trained machine learning model further includes a stay time in the unit counted for each unit by the unit stay time counting section.

In the present embodiment, as an example, the input data at the time of training of the machine learning model further includes a second feature amount obtained by converting a position of a member used for polishing or cleaning. On the premise of this, the conversion section 62 converts the position of the member used for polishing or cleaning into the second feature amount. In this case, the target data input to the trained machine learning model further includes the second feature amount for each member converted by the conversion section 62.

In the present embodiment, as an example, the input data at the time of training the machine learning model further includes recipe information including a command value for a unit included in the substrate processing apparatus. This command value is a set value of the above-described physical quantity of the object (for example, the rotation speed of the polishing table 23), and each set value of the physical quantity of the object is one value for each processing step. On the premise of this, the target data input to the trained machine learning model further includes recipe information including a command value for a unit included in the substrate processing apparatus.

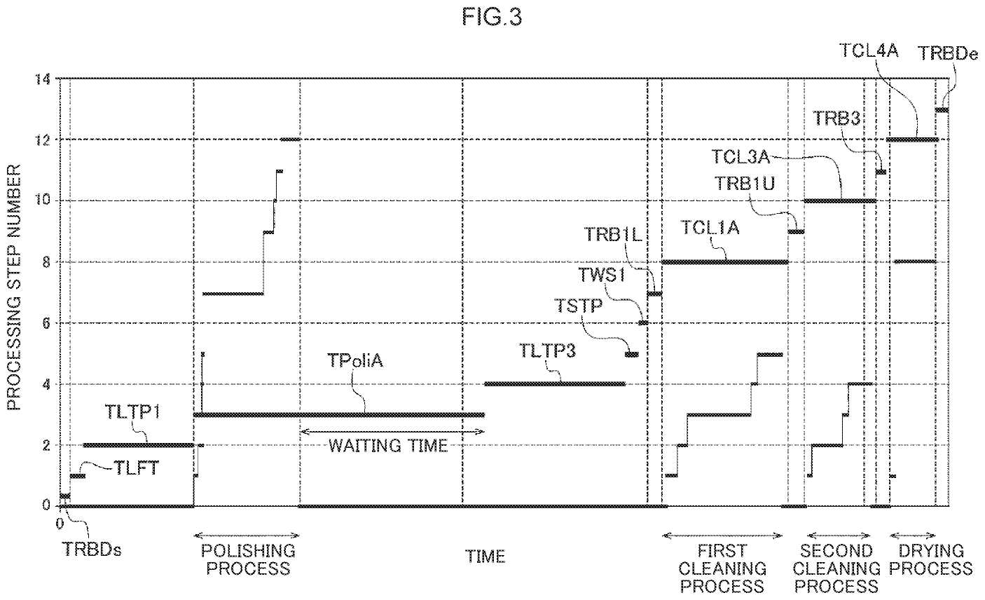

Next, the stay time of the substrate in each unit will be described with reference to FIG. 3. FIG. 3 is a graph illustrating an example of a stay time in each unit according to the present embodiment. In the graph of FIG. 3, the vertical axis represents a processing step number, and the horizontal axis represents time. FIG. 3 illustrates the stay time of each unit in the following processing. That is, the transport robot 12 delivers the substrate to the lifter 41, then the transport hand 45A of the first linear transporter 42 takes out the substrate from the lifter 41, and the transport hand 45A delivers the substrate W to the polishing device 21A at the second transport position TP2. After the polishing by the polishing device 21A, the transport hand 45D of the first linear transporter 42 receives the substrate from the polishing device 21A, delivers the substrate W to the swing transporter 44 at the fourth transport position TP4, and the swing transporter 44 vertically inverts the received substrate and places the substrate on the temporary placing stand 47. Thereafter, the lower hand of the transport robot 35 receives the substrate W and transports the substrate W to the cleaning device 31A. After the cleaning in the cleaning device 31A, the upper hand of the transport robot 35 takes out the substrate W from the cleaning device 31A and transports the substrate W to the cleaning device 31B. After the cleaning in the cleaning device 31B, the hand of the transport robot 36 takes out the substrate W from the cleaning device 31B and transports the substrate W to the substrate drying device 32. After the substrate drying device 32 dries the substrate, the transport robot 12 takes out the substrate from the substrate drying device 32.

In FIG. 3, TRBDs is a stay time of the substrate in the hand of the transport robot 12 before the polishing process, TLFT is a stay time of the substrate in the lifter 41, TLTP1 is a stay time of the substrate in the transport hand 45A of the first linear transporter 42, and TPoliA is a stay time of the substrate in the polishing device 21A. The stay time TPoliA of the substrate in the polishing device 21A includes not only the time of the polishing process but also a waiting time. This waiting time may also be further used as input data for training and inference of the machine learning model. TLTP3 is a stay time of the substrate in the transport hand 45D of the first linear transporter 42, TSTP is a stay time of the substrate in the swing transporter 44, TWS1 is a stay time of the substrate in the temporary placing stand, TRB1L is a stay time of the substrate in the lower hand of the transport robot 35, TCL1A is a stay time of the substrate in the cleaning device 31A, TRB1LU is a stay time of the substrate in the upper hand of the transport robot 35, TCL3A is a stay time of the substrate in the cleaning device 31B, TRB3 is a stay time of the substrate in the hand of the transport robot 36, TCL4A is a stay time of the substrate in the substrate drying device 32, and TRBDe is a stay time of the substrate in the hand of the transport robot 12 after drying.

As illustrated in FIG. 3, the polishing process has a plurality of processing steps, the first cleaning process also has a plurality of processing steps, the second cleaning process also has a plurality of processing steps, and the drying process also has a plurality of processing steps. A processing step number is assigned to each of these processing steps so that the processing step can be identified. Here, a description will be given below assuming that there are first to Nth (That is, the processing step numbers are 1 to N, and N is a natural number.) processing steps.

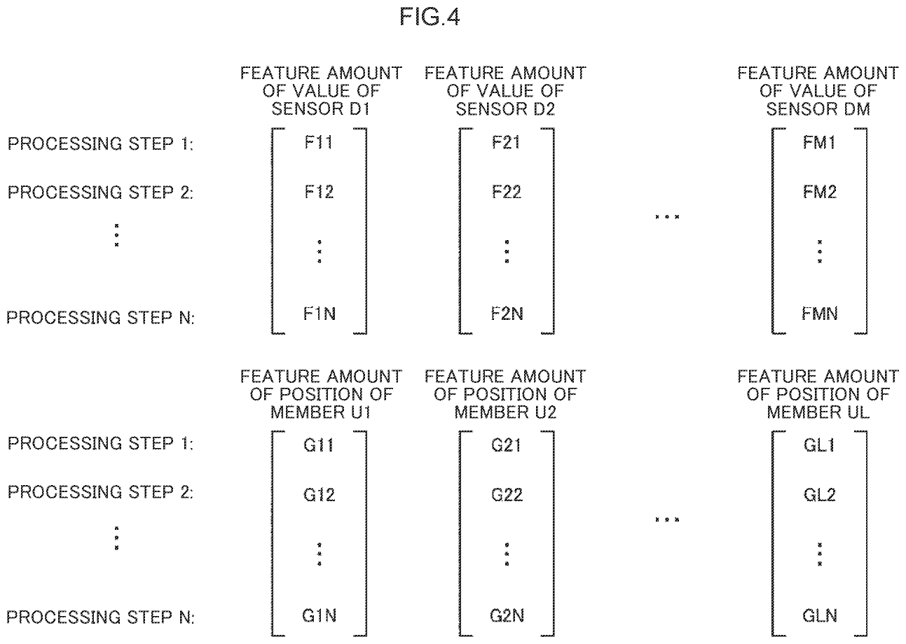

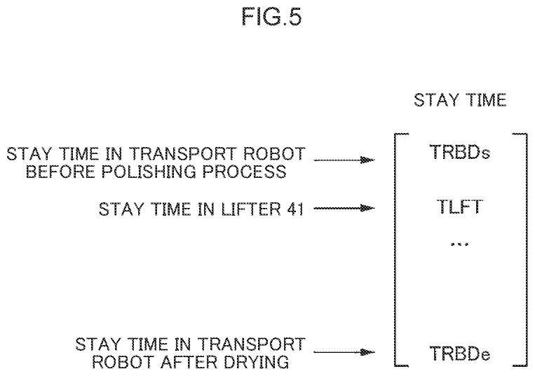

Next, an example of a data structure of the feature amount included in the input data input to the machine learning model will be described with reference to FIGS. 4 and 5. Here, the substrate processing apparatus 1 will be described assuming that there are M (M is a natural number) sensors from a sensor DI to a sensor DM. FIG. 4 is an example of a data structure of a feature amount included in the input data input to the machine learning model. As illustrated in FIG. 4, a feature amount of a value of the sensor D1 is represented by an array (or vector) having the feature amounts of the processing steps 1 to N as elements. Similarly, a feature amount of a value of the sensor D2 is represented by an array (or vector) having the feature amounts of the processing steps 1 to N as elements, and a feature amount of a value of the sensor DM is represented by an array (or vector) having the feature amounts of the processing steps 1 to N as elements. As described above, the feature amount of the value of the sensor Di (i is an integer from 1 to M) included in the input data input to the machine learning model is represented by an array (or vector) having each of the feature amounts of the processing steps 1 to N as an element.

Here, each of the members included in the above-described substrate processing apparatus 1 will be described as members U1 to UL (L is a natural number). For example, the processor 6 stores positions of the members 1 to L included in the substrate processing apparatus 1 in the storage section 7 in time series. The positions of the members U1 to UL may be calculated by a predetermined conversion formula from a command signal by which the unit control section 51 commands the members U1 to UL to operate, may be determined from a known correspondence relationship between the command signal and the positions, or may be positions detected by the sensors. As illustrated in FIG. 4, the feature amount of the position of the member U1 is represented by an array (or vector) having the feature amounts of the processing steps 1 to N as elements. Similarly, the feature amount of the position of the member U2 is represented by an array (or vector) having the feature amounts of the processing steps 1 to N as elements. Similarly, the feature amount of the position of the member UL is represented by an array (or vector) having the feature amounts of the processing steps 1 to N as elements. As described above, the feature amount of the position of the member Uj (j is an integer from 1 to L) included in the input data input to the machine learning model is represented by an array (or vector) having each of the feature amounts of the processing steps 1 to N as an element.

FIG. 5 is an example of a data structure of the stay time for each unit included in the input data input to the machine learning model. As illustrated in FIG. 5, the stay time for each unit included in the input data input to the machine learning model is represented by an array (or vector) having each stay time of the substrate for each unit as an element.

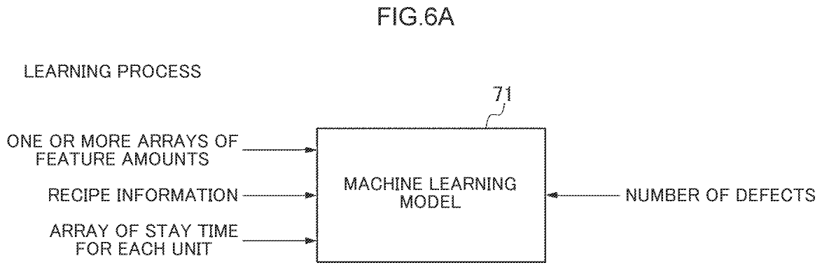

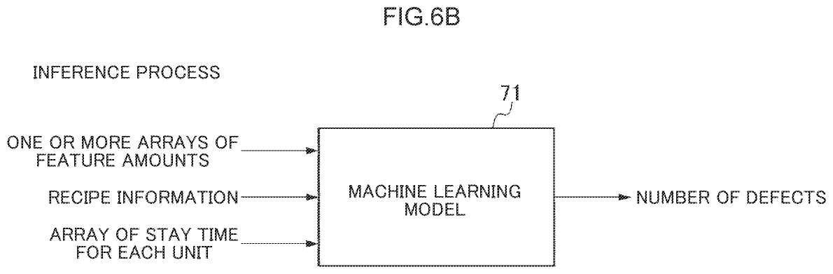

Next, an example of a learning process and an inference process of the machine learning model 71 will be described using FIGS. 6A and 6B. FIG. 6A is a schematic diagram for explaining an example of the learning process of the machine learning model. FIG. 6B is a schematic diagram for explaining an example of the inference process of the machine learning model. As illustrated in FIG. 6A, in the learning process, the machine learning model 71 is trained using the learning data set whose input data is one or more arrays of feature amounts for each processing step, the recipe information, and the array of stay time for each unit described above with reference to FIG. 4 and whose output data is the number of defects of the substrate. As illustrated in FIG. 6B, in the inference process, when one or more arrays of feature amounts for each processing step, recipe information, and an array of stay times for each unit are input to the machine learning model 71 for the target substrate, the number of defects of the target substrate is output. Here, the feature amount in the inference process is the same type as the feature amount in the learning process.

Note that the one or more arrays of the feature amounts for each processing step, the recipe information, and the array of the stay time for each unit are used as the input data of the machine learning, but any one or a combination of any two may be used.

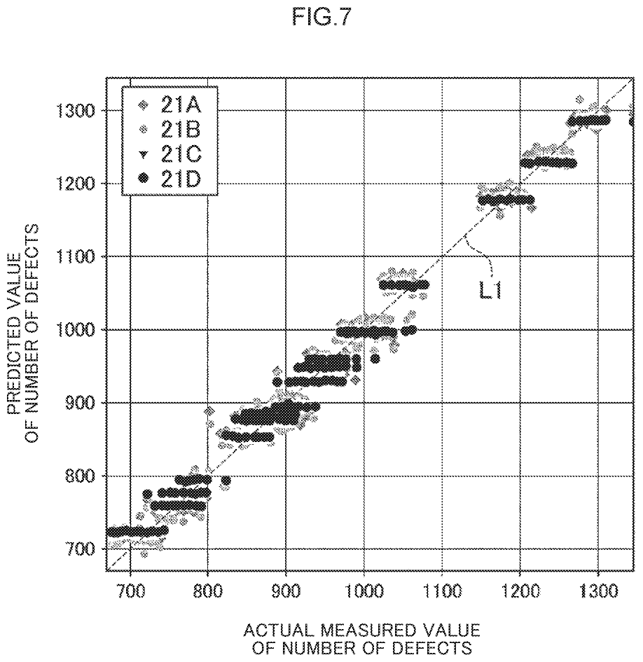

FIG. 7 is an example of a graph for comparing an actual measured value of the number of defects with a predicted value of the number of defects. In FIG. 7, the vertical axis represents the predicted value of the number of defects, and the horizontal axis represents the actual measured value of the number of defects, and results are plotted while varying the shade of the plot for each of the polishing devices 21A, 21B, 21C, and 21D. As a plot group is distributed closer to a broken line L1, the prediction accuracy of the number of defects is higher. As illustrated in FIG. 7, the plot group is distributed close to the broken line L1 in any polishing device, and it is indicated that the prediction accuracy of the number of defects is high in any polishing device.

As described above, the substrate processing apparatus 1 according to the present embodiment includes: at least one sensor that detects a physical quantity of an object during polishing and/or during cleaning and/or during drying of a substrate; the conversion section 62 that converts a sensor value during polishing and/or during cleaning and/or during drying detected by the sensor into a feature amount for each processing step with respect to a trained machine learning model; and the inference section 64 that outputs a predicted value of the number of defects in the substrate by inputting target data including the feature amount to the trained machine learning model 71. The trained machine learning model 71 is trained using a learning data set whose input data includes a feature amount obtained by converting a sensor value during polishing and/or during cleaning detected by a sensor in a target production line or a production line of the same type as the target production line for each processing step and whose output data is the number of defects in the substrate.

According to this configuration, since at least one predicted value of the number of defects, the size of the defect, and the position of the defect of the substrate after substrate processing is obtained without being inspected by a defect inspection apparatus, it is possible to estimate whether or not the substrate after the substrate processing is a defective product without being inspected by the defect inspection apparatus.

### First Modification of Machine Learning Model

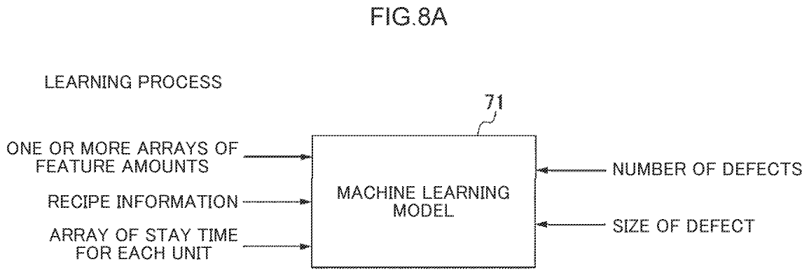

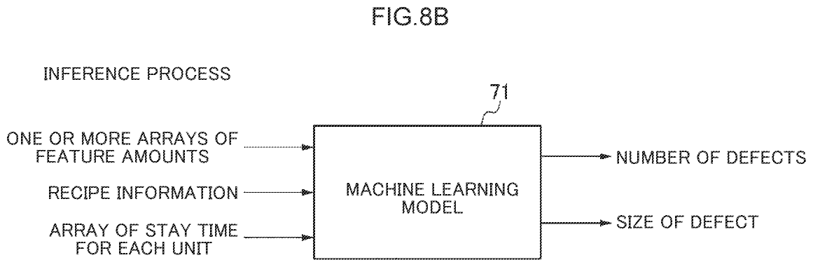

Next, a first modification of the learning process and the inference process of the machine learning model 71 will be described with reference to FIGS. 8A and 8B. FIG. 8A is a schematic diagram for explaining the first modification of the learning process of the machine learning model. FIG. 8B is a schematic diagram for explaining the first modification of the inference process of the machine learning model. As illustrated in FIG. 8A, in the learning process, the machine learning model 71 is trained using the learning data set whose input data is the one or more arrays of feature amounts for each processing step, the recipe information, and the array of stay time for each unit described above with reference to FIG. 4, and whose output data is the number of defects of the substrate and the size of the defect of the substrate. As illustrated in FIG. 8B, in the inference process, when the one or more arrays of feature amounts for each processing step, the recipe information, and the array of stay time for each unit are input to the machine learning model 71 for the target substrate, the number of defects of the target substrate and the size of the defect of the target substrate are output. The feature amount in the inference process is the same type as the feature amount in the learning process.

### Second Modification of Machine Learning Model

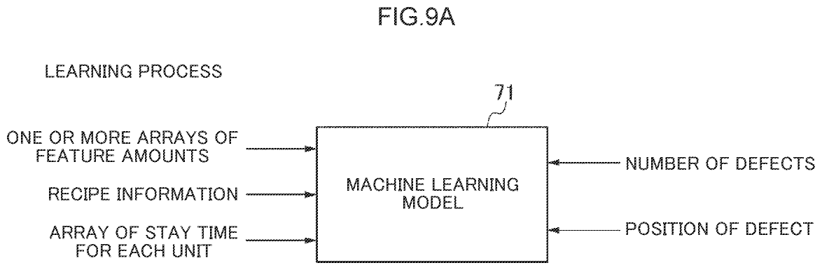

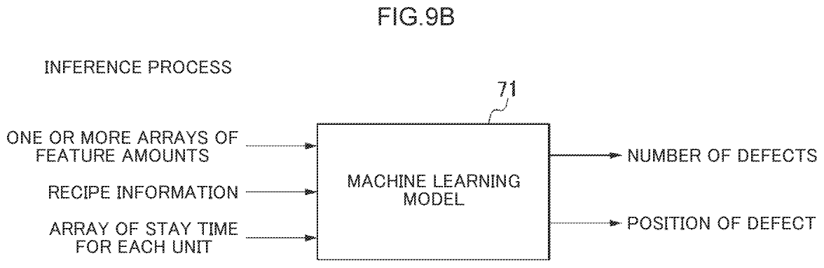

Next, a second modification of the learning process and the inference process of the machine learning model 71 will be described with reference to FIGS. 9A and 9B. FIG. 9A is a schematic diagram for explaining the second modification of the learning process of the machine learning model. FIG. 8B is a schematic diagram for explaining the second modification of the inference process of the machine learning model. As illustrated in FIG. 9A, in the learning process, the machine learning model 71 is trained using the learning data set whose input data is the one or more arrays of feature amounts for each processing step, the recipe information, and the array of stay time for each unit described above with reference to FIG. 4, and whose output data is the number of defects of the substrate and the position of the defect of the substrate. As illustrated in FIG. 9B, in the inference process, when the one or more arrays of feature amounts for each processing step, the recipe information, and the array of stay time for each unit are input to the machine learning model 71 for the target substrate, the number of defects of the target substrate and the position of the defect of the target substrate are output. Here, the feature amount in the inference process is the same type as the feature amount in the learning process.

### Third Modification of Machine Learning Model

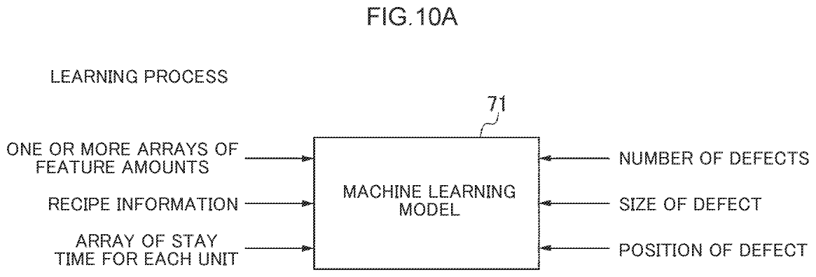

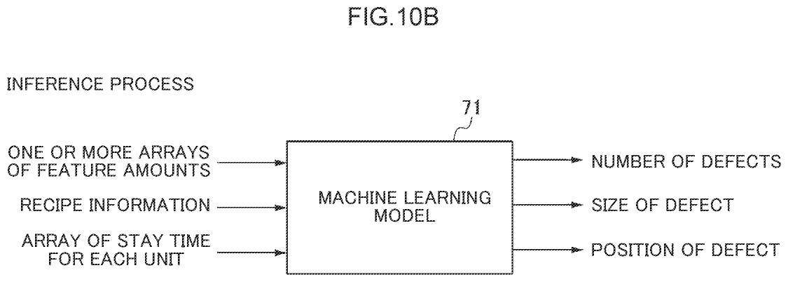

Next, a third modification of the learning process and the inference process of the machine learning model 71 will be described with reference to FIGS. 10A and 10B. FIG. 10A is a schematic diagram for explaining the third modification of the learning process of the machine learning model. FIG. 10B is a schematic diagram for explaining the third modification of the inference process of the machine learning model. As illustrated in FIG. 10A, in the learning process, the machine learning model 71 is trained using the learning data set whose input data is the one or more arrays of feature amounts for each processing step, the recipe information, and the array of stay time for each unit described above with reference to FIG. 4, and whose output data is the number of defects of the substrate, the size of the defect of the substrate, and the position of the defect of the substrate. As illustrated in FIG. 9B, in the inference process, when the one or more arrays of feature amounts for each processing step, the recipe information, and the array of residence time for each unit are input to the machine learning model 71 for the target substrate, the number of defects in the target substrate, the size of the defect in the target substrate, and the position of the defect in the target substrate are output. Here, the feature amount in the inference process is the same type as the feature amount in the learning process.

Note that not only the combination of the output data of the first to third modifications but also the inference section 64 may output one or any two of the number of defects, the size of the defect, and the position of the defect in the target substrate. As described above, the inference section 64 may output at least one predicted value of the number of defects, the size of the defect, and the position of the defect in the target substrate by inputting the target data including the feature amount to the trained machine learning model.

In the present embodiment, the substrate processing apparatus 1 includes the processor 6 and the storage section 7, but the present invention is not limited thereto.

### First Modification of Present Embodiment

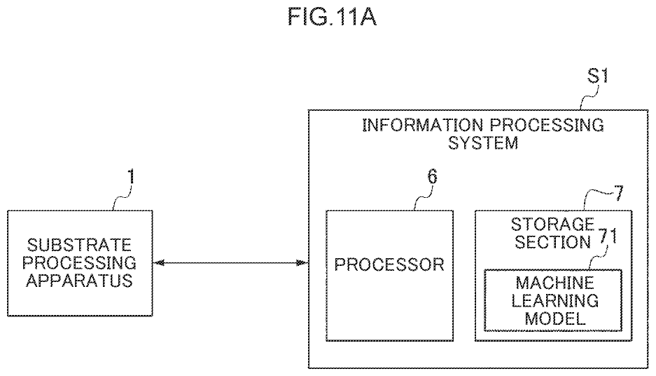

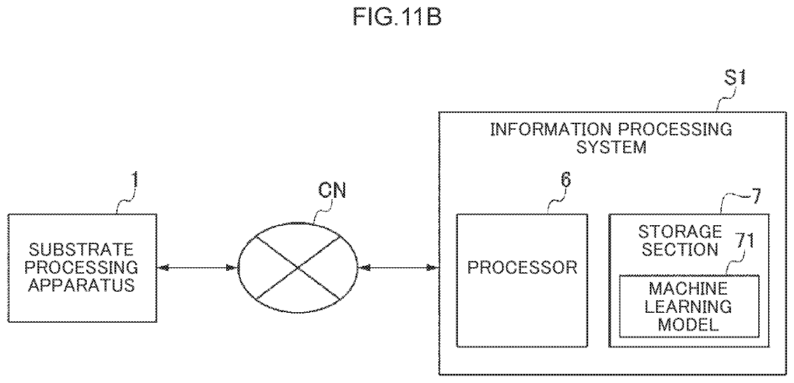

FIG. 11A is a schematic configuration diagram according to a first modification of the present embodiment. As illustrated in FIG. 11A, an information processing system S1 connected to the substrate processing apparatus 1 so as to be able to exchange information with the substrate processing apparatus 1 is provided, the information processing system S1 includes the processor 6 and the storage section 7 in which the machine learning model 71 is stored, and the processor 6 may function as the unit stay time counting section 61, the conversion section 62, the learning section 63, the inference section 64, the regression analysis section 65, and the reception section 66 by reading and executing a program from the storage section 7.

### Second Modification of Present Embodiment

FIG. 11B is a schematic configuration diagram according to a second modification of the present embodiment. As illustrated in FIG. 11B, an information processing system S1 connected to the substrate processing apparatus 1 via a communication circuit network CN so as to be able to exchange information with the substrate processing apparatus 1 is provided, the information processing system S1 includes the processor 6 and the storage section 7 in which the machine learning model 71 is stored, and the processor 6 may function as the unit stay time counting section 61, the conversion section 62, the learning section 63, the inference section 64, the regression analysis section 65, and the reception section 66 by reading and executing a predetermined program from the storage section 7.

### Third Modification of Present Embodiment

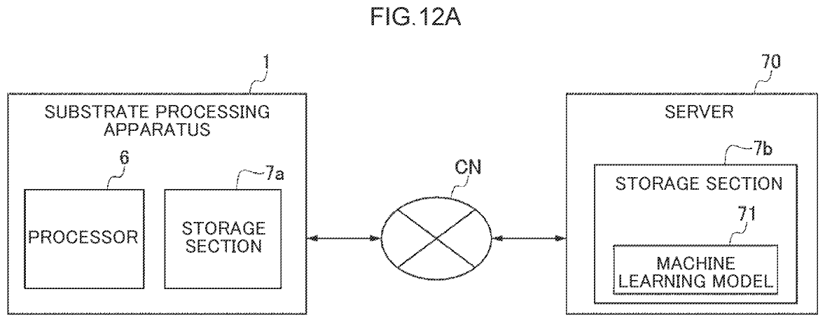

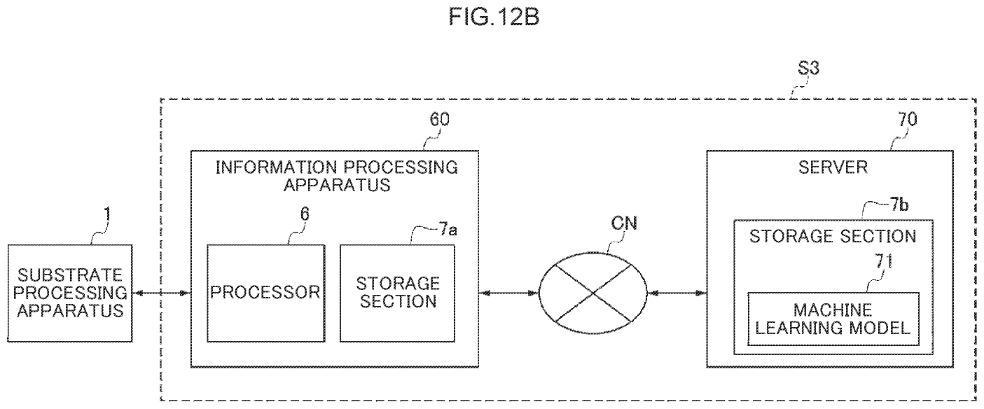

FIG. 12A is a schematic configuration diagram according to a third modification of the present embodiment. As illustrated in FIG. 12A, the substrate processing apparatus 1 may include a server 70 connected to the substrate processing apparatus 1 via a communication circuit network CN so as to be able to exchange information, the substrate processing apparatus 1 may include the processor 6 and the storage section 7a storing a predetermined program, and the server 70 may include the storage section 7b storing the machine learning model 71. In this case, the processor 6 of the substrate processing apparatus 1 may function as the unit stay time counting section 61, the conversion section 62, the learning section 63, the inference section 64, the regression analysis section 65, and the reception section 66 by reading and executing a predetermined program from the storage section 7a, and the inference section 64 may output at least one predicted value of the number of defects, the size of the defect, and the position of the defect in the target substrate by inputting target data including the feature amount to the trained machine learning model 71 of the server 70.

### Fourth Modification of Present Embodiment

FIG. 12A is a schematic configuration diagram according to a third modification of the present embodiment. As illustrated in FIG. 12A, a configuration may include the substrate processing apparatus 1 and an information processing system S3, and the information processing system S3 may include an information processing apparatus 60 connected to the substrate processing apparatus 1 so as to be able to exchange information, and a server 70 connected to the information processing apparatus 60 so as to be able to exchange information via a communication circuit network CN. In this case, the information processing apparatus 60 may include the processor 6 and the storage section 7a in which a predetermined program is stored, and the server 70 may include the storage section 7b in which the machine learning model 71 is stored. Here, the processor 6 of the information processing apparatus 60 may function as the unit stay time counting section 61, the conversion section 62, the learning section 63, the inference section 64, the regression analysis section 65, and the reception section 66 by reading and executing a predetermined program from the storage section 7a, and the inference section 64 may output at least one predicted value of the number of defects, the size of the defect, and the position of the defect in the target substrate by inputting target data including the feature amount to the trained machine learning model 71 of the server 70.

As described above, the information processing systems S1, S2, and S3 may include the conversion section 62 that converts the sensor value during polishing and/or during cleaning and/or during drying of the substrate detected by the sensor included in the substrate processing apparatus 1 into the feature amount for each processing step with respect to the trained machine learning model with respect to the trained machine learning model, and the inference section 64 that outputs at least one predicted value among the number of defects in the substrate, the size of the defect, and the position of the defect in the substrate by inputting the target data including the feature amount. Here, this trained machine learning model is trained using a learning data set whose input data includes a feature amount obtained by converting a sensor value during polishing and/or during cleaning detected by a sensor in a target production line or a production line of the same type as the target production line for each processing step and whose output data is at least one of the number of defects, the size of the defect, and the position of the defect in the substrate.

According to this configuration, since at least one predicted value of the number of defects, the size of the defect, and the position of the defect of the substrate after substrate processing is obtained without being inspected by a defect inspection apparatus, it is possible to estimate whether or not the substrate after the substrate processing is a defective product without being inspected by the defect inspection apparatus.

Note that at least some of the functions of the information processing systems S1, S2, and S3 or the processor 6 described in the above-described embodiment may be configured by hardware or software. In the case of being configured by software, a program that implements at least a part of the functions of the information processing system S1, S2, and S3 or the processor 6 may be stored in a computer-readable recording medium and read and executed by a computer. The recording medium is not limited to a removable recording medium such as a magnetic disk or an optical disk, and may be a fixed recording medium such as a hard disk device or a memory.

Furthermore, a program that implements at least some of the functions of the information processing systems S1, S2, and S3 or the processor 6 may be distributed via a communication line (including wireless communication) such as the Internet. Moreover, the program may be distributed via a wired line or a wireless line such as the Internet or stored in a recording medium in an encrypted, modulated, or compressed state.

Moreover, the information processing systems S1, S2, and S3 may be caused to function by one or a plurality of information devices. In a case where a plurality of information devices is used, one of the information devices may be a computer, and the computer may execute a predetermined program to implement a function as at least one unit of the information processing systems S1, S2, and S3.

As described above, the present invention is not limited to the above-described embodiments as it is, and can be embodied by modifying the constituent elements without departing from the gist of the present invention in the implementation stage. Furthermore, various inventions can be formed by appropriately combining a plurality of constituent elements disclosed in the above embodiments. For example, some constituent elements may be deleted from all the constituent elements shown in the embodiments. Moreover, constituent elements in different embodiments may be appropriately combined.

### Reference Signs List

1 substrate processing apparatus

50 control section

51 unit control section

6 processor

61 unit stay time counting section

62 conversion section

63 learning section

64 inference section

65 regression analysis section

66 reception section

7 storage section

71 machine learning model

8 display device

S1, S2, S3 information processing system

1. A substrate processing apparatus comprising:
at least one sensor that detects a physical quantity of an object during polishing and/or during cleaning and/or during drying of a substrate;
a conversion section that converts a sensor value during polishing and/or during cleaning and/or during drying detected by the sensor into a feature amount for each processing step with respect to a trained machine learning model; and
an inference section that outputs at least one predicted value of a number of defects, a size of a defect, and a position of a defect in a target substrate by inputting target data including the feature amount to the trained machine learning model, wherein
the trained machine learning model is trained using a learning data set whose input data includes a feature amount obtained by converting a sensor value during polishing and/or during cleaning detected by the sensor in a target production line or a production line of an identical type with the target production line for each processing step, and whose output data is at least one of a number of defects, a size of a defect, and a position of a defect in the substrate.

2. The substrate processing apparatus according to claim 1, wherein
the input data at a time of training of the machine learning model further includes a stay time of staying in a unit counted for each unit included in the substrate processing apparatus,
the substrate processing apparatus further comprises a unit stay time counting section that counts a stay time in the unit for each unit included in the substrate processing apparatus, and
the target data input to the trained machine learning model further includes the stay time in the unit counted for each unit by the unit stay time counting section.

3. The substrate processing apparatus according to claim 1, wherein
the input data at a time of training of the machine learning model further includes a second feature amount obtained by converting a position of a member used for polishing or cleaning,
the conversion section converts the position of the member used for polishing or cleaning into the second feature amount, and
the target data input to the trained machine learning model further includes the second feature amount for each member converted by the conversion section.

4. The substrate processing apparatus according to claim 1, wherein
the input data at a time of training of the machine learning model further includes recipe information including a command value for a unit included in the substrate processing apparatus, and
the target data input to the trained machine learning model further includes recipe information including a command value for a unit included in the substrate processing apparatus.

5. The substrate processing apparatus according to claim 1, further comprising:
a regression analysis section that outputs a correlation parameter representing a correlation with one of a number of defects, a size of a defect, and a position of a defect in the substrate for each of a plurality of sensor values according to a predetermined regression analysis algorithm;
a reception section that receives at least one sensor that outputs a sensor value that is a basis of the feature amount included in the input data of the machine learning model; and
a learning section that trains the machine learning model again with the feature amount obtained by converting the sensor value of the received sensor, wherein
the inference section outputs the predicted value using the machine learning model trained again by the learning section.

6. An information processing system comprising:
a conversion section that converts a sensor value during polishing and/or during cleaning and/or during drying of a substrate detected by a sensor included in a substrate processing apparatus into a feature amount for each processing step with respect to a trained machine learning model; and
an inference section that outputs at least one predicted value of a number of defects in the substrate, a size of a defect, and a position of a defect in the substrate by inputting target data including the feature amount, wherein
the trained machine learning model is trained using a learning data set whose input data includes a feature amount obtained by converting a sensor value during polishing and/or during cleaning detected by the sensor in a target production line or a production line of an identical type with the target production line for each processing step, and whose output data is at least one of a number of defects, a size of a defect, and a position of a defect in the substrate.
